(19) United States
(12) Patent Application Publication
(10) Pub. No.: US 2011/0049552 A1
(43) Pub. Date: Mar. 3, 2011

(54) LIGHT EMITTING DIODE PACKAGE

(76) Inventors: In Joon Pyeon, Gyunggi-do (KR); Hong Min Kim, Gyunggi-do (KR)

(21) Appl. No.: 12/810,097

(22) PCT Filed: Dec. 24, 2008
(86) PCT No.: PCT/KR2008/007692

§ 371 Date: Nov. 18, 2010

(30) Foreign Application Priority Data
Dec. 24, 2007 (KR) 10-2007-0136265
Dec. 24, 2008 (KR) 10-2008-0133439

(51) Int. Cl. H01L 23/28; H01L 33/00

(52) U.S. Cl. 257/98; 257/99; 257/E23.116; 257/E33.059

(57) ABSTRACT

There is provided a light emitting diode (LED) package. The LED package includes A light emitting diode (LED) package includes a pair of lead frames connected with at least one LED chip through a metal wire, a package body integrally fixed with the lead frames and having a cavity having an open top, a lead frame bent downwardly to a lower part of an external mounting surface of the package body, a light-transmissive, transparent resin covering the LED chip and filling the cavity, a recess formed in a bottom surface of the cavity, in which the LED chip is mounted, and a transparent resin including a fluorescent material formed in the recess and the cavity. Accordingly, the amount of light-transmissive, transparent resin filling the cavity is reduced to save on manufacturing costs, and the height of the resin is lowered to improve the luminance of light. Also, the height of the package body is lowered, contributing to manufacturing a small product.

### TECHNICAL FIELD

The present invention relates to a light emitting diode (LED) package, and more particularly, to an LED package improved such that the amount of transmissive transparent resin, injected to protect an LED chip, is reduced and the height of the resin is lowered, thereby improving the luminance of light.

### BACKGROUND ART

In general, a light emitting diode (LED) is an electric component that produces minority carriers (electrons or holes) injected using p-n junctions in semiconductors and converts electric energy into light energy by recombination of the minority carriers to thereby emit light. That is, when a forward voltage is applied to a semiconductor having a particular element, electrons and holes move across the junction of the anode and the cathode and recombine with each other. The level of energy generated when the electrons and the holes recombine with each other is lower than that of energy generated when the electrons and the holes are separated from each other. The difference in energy level makes the LED emit light.

LEDs have been used in home appliances, remote controllers, sign boards, displays, and various kinds of automatic devices because they can irradiate light with high efficiency at low voltage.

FIG. 1 is a longitudinal cross-sectional view illustrating a general LED package. As shown in FIG. 1, an LED package 1 according to the related art has a light emitting chip 15 at a central area thereof. The light emitting chip 15, which serves as a light source, generates light when power is supplied.

The light emitting chip 15 is electrically connected to a pair of lead frames 13 and 14, separated from each other, using metal wires 16 and 17, respectively.

While the anode and cathode lead frames 13 and 14 are fixed integrally to a package body 11 that is mainly formed of resin by injection molding, an end portion of each of the lead frames 13 and 14 is exposed to the outside so that the end portion can be connected to the external power supply.

The package body 11 includes a cavity C whose upper part is open. The light emitting chip 15 is mounted in the cavity C. The lead frames 13 and 14 are connected to the metal wires 16 and 17, respectively, by wire bonding, and exposed to the outside through the cavity C.

The cavity C is filled with light-transmissive, transparent resin 18 to protect the light emitting chip 15 and the metal wires 13 and 14 against the environment. The light-transmissive, transparent resin 18 may selectively include various kinds of phosphors, depending on what color of light an LED emits.

A reflective member 12, coated with a reflective material, may be provided on inner inclined surfaces of the cavity C so as to increase reflectance to light generated from the light emitting chip 15.

Specifications that determine the characteristics of the LED package include color, luminance and a luminous intensity range. The characteristics of the LED package are primarily affected by the characteristics of the light emitting chip 15. Secondarily, a structure of the package body 11, mounted with the light emitting chip 15, and the amount of the light-transmissive transparent resin 18 filling the cavity C affect the characteristics of the LED package.

FIG. 2 is a graph illustrating changes in luminance according to the dotting amount of light-transmissive, transparent resin of a general LED package. A 0.6T LED package is shown in a), and a 0.8T LED package is shown in b).

As shown in FIGS. 2(a) and 2(b), the smaller the dotting amount of the light-transmissive, transparent resin 18 filling the cavity C of the package body 11 is, the higher the luminance is.

However, even though luminance increases by reducing the dotting amount of the light-transmissive, transparent resin 18, a reduction in height of the transparent resin 18 causes the metal wires 16 and 17 to be exposed to the outside.

### DISCLOSURE OF INVENTION

### Technical Problem

An aspect of the present invention provides a light emitting diode (LED) package capable of improving the luminance of light by reducing the amount of light-transmissive, transparent resin filling a cavity while lowering the height of the resin, and of achieving miniaturization by decreasing the package size.

### Technical Solution

According to an aspect of the present invention, there is provided a light emitting diode (LED) package including: a pair of lead frames connected with at least one LED chip through a metal wire; a package body integrally fixed with the lead frames and having a cavity with an open top; a lead frame bent downwardly to a lower part of an external mounting surface of the package body; a light-transmissive, transparent resin covering the LED chip and filling the cavity; a recess formed in a bottom surface of the cavity, in which the LED chip is mounted; and a transparent resin including a fluorescent material formed in the recess and the cavity.

The recess may have a depth ranging from 50 μm to 400 μm

The fluorescent material may be at least one of YAG-based, TAG-based, silicate-based, sulfide-based and nitride-based materials.

The recess may be provided between respective facing ends of the lead frames in the form of a groove having a predetermined depth.

An end portion of the lead frame facing an outer surface of the LED chip may have a lower inclined surface on which a reflective member reflecting light from the LED chip is provided.

The cavity may have an upper inclined surface on which a reflective member reflecting light from the LED chip is provided.

### ADVANTAGEOUS EFFECTS

According to the present invention, a recess is provided in a lead frame or between facing lead frames for the mounting of an LED chip, so that the height of a package body is lowered and thus the amount of transmissive transparent resin filling a cavity is reduced, thereby saving on manufacturing costs, improving the luminance of light and contributing to manufacturing a small product.

### BRIEF DESCRIPTION OF DRAWINGS

FIG. 1 is a longitudinal cross-sectional view illustrating a general LED package.

FIG. 2 is a graph illustrating changes in luminance according to the dotting amount of light-transmissive, transparent resin of a general LED package, wherein A 0.6T LED package is shown in a), and a 0.8T LED package is shown in b).

FIG. 3 is a cross-sectional view of an LED package according to a first exemplary embodiment of the present invention.

FIG. 4 is a cross-sectional view of an LED package according to a second exemplary embodiment of the present invention.

FIG. 5 is a V-shaped distortion structure formed in an LED layer according to the present invention, wherein (a) is a cross-sectional view illustrating a flat growth plane and a inclined growth plane, (b) is a sectional photographic image in which the inclined growth plane is indicated by dotted lines, and (c) is a plan photographic image showing unevenness of a surface.

FIGS. 6(a) through 6(c) are schematic views illustrating the process of forming an external lead frame in the LED package according to the present invention.

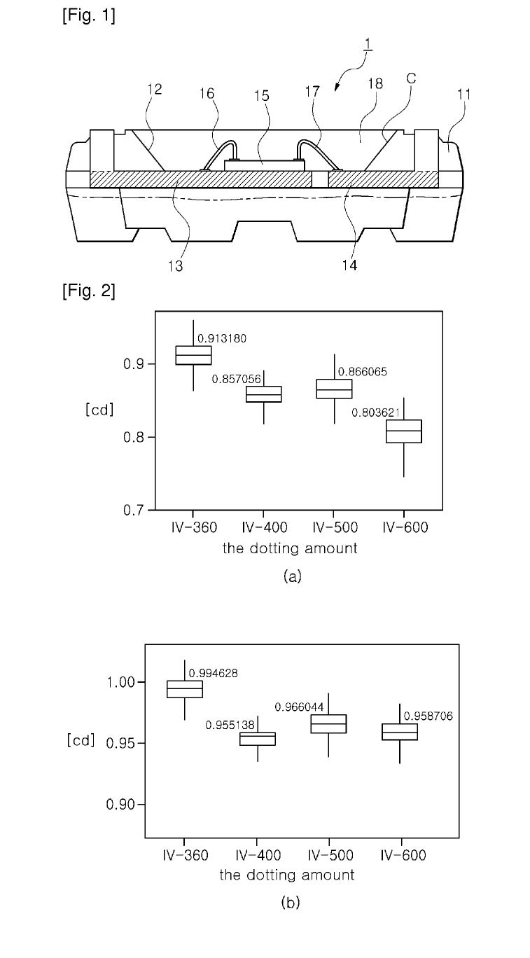

### MODE FOR THE INVENTION

Exemplary embodiments of the present invention will now be described in detail with reference to the accompanying drawings.

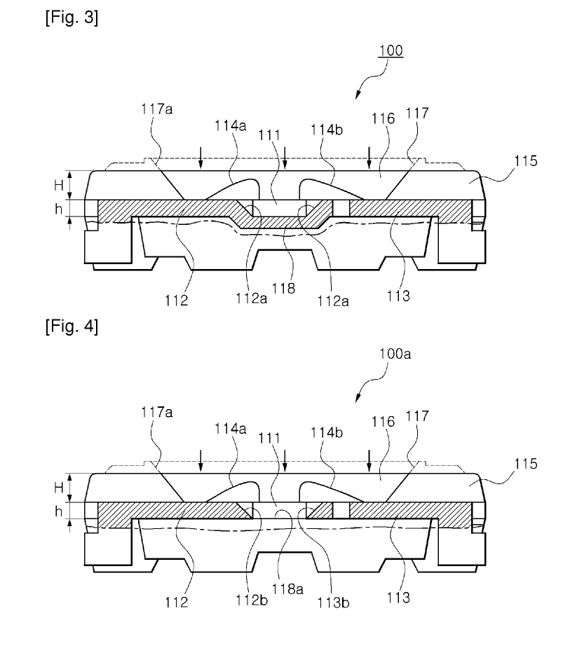

FIG. 3 is a cross-sectional view of a light emitting diode (LED) package according to a first exemplary embodiment of the present invention.

A package 100 according to the first exemplary embodiment of the present invention includes an LED chip 111, lead frames 112 and 113, a package body 115, light-transmissive, transparent resin 116, and a recess 118 in which the LCD chip 111 is mounted.

The LED chip 111 is configured as a light emtting device that generates light when power is applied thereto, and the LED chip 111 has the positive pole and the negative pole disposed horizontally at its top surface.

The LED chip 111 is bonded with one set of ends of a pair of metal wires 114a and 114b, and the lead frames 112 and 113 are bonded with the other set of ends of the pair of metal wires 114a and 114b.

The package body 115 is a molded structure, which is formed of resin by injection-molding to form a cavity with the closed bottom and the open top.

The cavity 117 has an upper inclined surface inclined at a predetermined angle. A reflective member 117a of a metallic material having high reflectance, such as Al, Ag or Ni, may be provided on the upper inclined surface in order to reflect light generated from the LED chip 111.

The package body 115 is molded integrally with the pair of lead frames 112 and 113 for the fixation thereof. A portion of a top surface of an end of each of the lead frames 112 and 113 is exposed to the outside through the bottom of the cavity 117.

The other end of each of the lead frames 112 and 113 is exposed to an outer surface of the package body 115 to form a connection with external power supply.

The recess 118 may be formed in a lead frame 112 of the pair of lead frames 112 and 113, on which the LED chip 111 is mounted.

FIG. 4 is a cross-sectional view of an LED package according to a second exemplary embodiment of the present invention.

Referring to FIG. 4, unlike the LED package including the recess 118 of the first exemplary embodiment, the LED package according to the second exemplary embodiment includes a groove 118a between the respective facing ends of the lead frames 112 and 113. The groove 118 is formed to a predetermined depth from the bottom of the cavity 117 when the package body 115 is molded.

The light-transmissive, transparent resin 116 is a transparent resin material such as epoxy, silicon and resin, which fills the cavity 117 to cover the LED chip 111 and the metal wires 114a and 114b for the protection from the external environments.

The transparent resin 116 may include a fluorescent material for wavelength conversion. The fluorescent material may be one of YAG-based, TAG-based, silicate-based, sulfide-based and nitride-based fluorescent materials that can convert light generated from the LED chip into white light

The YAG-based and TAG-based fluorescent materials may be selected from the group consisting of (Y, Tb, Lu, Sc, La, Gd, Sm)3(Al, Ga, In, Si, Fe)5(O, S)12:Ce, and the silicate-based fluorescent material may be selected from the group consisting of (Sr, Ba, Ca, Mg)2SiO4: (Eu, F, Cl). The Sulfide-based fluorescent material may be selected from the group consisting of (Ca,Sr)S:Eu and (Sr,Ca,Ba)(Al,Ga)2S4:Eu. The nitride-based fluorescent material may be selected from the group consisting of (Sr, Ca, Si, Al, O)N:Eu (e.g., CaAlSiN4:Eu β-SiAlON:Eu) and Ca-α SiAlON:Eu-based fluorescent materials such as (Cax,My)(Si,Al)12(O,N)16, where M denotes at least one of europium (Eu), terbium (Tb), ytterbium (Yb) and erbium (Er), and x and y meet the conditions of 0.05<(x+y)<0.3, 0.02<x<0.27 and 0.03<y<0.3.

White light may be obtained by using a yellow (Y) fluorescent material, or green (G) and red (R) fluorescent materials, or Y, G and R fluorescent materials in a blue (B) LED chip. The Y, G and R fluorescent materials are excited by the blue LED chip to thereby emit yellow light, green light and red light, respectively. The yellow, green and red light is mixed with a portion of blue light emitted from the blue LED chip to thereby output white light.

The blue LED chip may employ a group-III-nitride semiconductor that is being commonly used. A substrate of the nitride-based semiconductor may be selected from the group consisting of sapphire, spinel (MgAl204), SiC, Si, ZnO, GaAs, and GaN substrates.

A buffer layer may be further provided on the substrate. The buffer layer may be formed of one selected from the group consisting of nitride semiconductor-based and carbide-based materials.

An n-type nitride semiconductor layer is formed on the buffer layer, and the n-type nitride semiconductor layer may include an n-type GaN-based semiconductor layer and an n-type superlattice layer. The n-type nitride semiconductor layer may include an undoped GaN layer; an n-type GaN contact layer; an n-type GaN layer on the n-type GaN contact layer; and an n-type superlattice layer on the n-type GaN layer. The n-type superlattice layer may have a multilayer structure of alternating layers of GaN/InGaN-based materials, AlGaN/GaN-based materials or AlGaN/GaN/InGaN-based materials. An n-type electrode may be further provided on the n-type GaN-based semi-conductor layer. A section of the n-type GaN-based semiconductor layer may have a V-shaped distortion structure. The V-shaped distortion structure includes both a flat growth plane and an inclined growth plane.

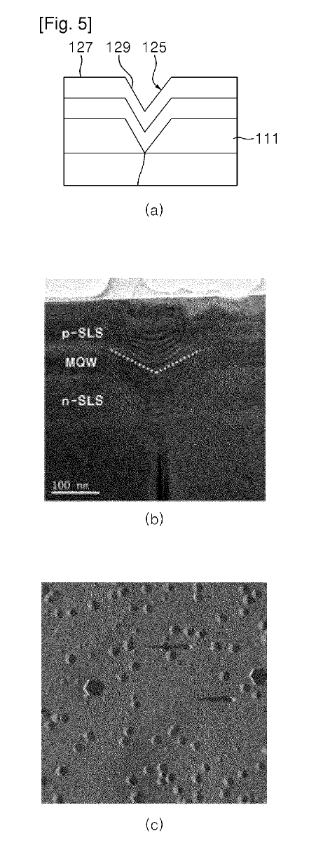

FIG. 5 illustrates a V-shaped distortion structure formed in an LED layer according to the present invention, wherein (a) is a cross-sectional view illustrating a flat growth plane and an inclined growth plane, (b) is a sectional photographic image in which the inclined growth plane is indicated by dotted lines, and (c) is a plan photographic image showing unevenness on a surface.

The LED chip 111 is an n-type nitride semiconductor layer, and a V-shaped distortion structure 125 includes a flat growth plane 127 and an inclined growth plane 129. In (b) of FIG. 5, the inclined growth plane is indicated by dotted lines.

An active layer is formed on the n-type nitride semiconductor layer, and the active layer has at least one quantum well layer. The quantum well layer may be formed of InGaN or GaN. The active layer may further include at least one quantum barrier layer. The quantum barrier layer may be formed of InGaN, GaN or AlGaN. A band gap of the quantum barrier layer is greater than that of the quantum well layer.

A p-type nitride semiconductor layer is formed on the active layer. The p-type nitride semiconductor layer includes a p-type superlattice layer and a p-type GaN-based semi-conductor layer. The p-type superlattice layer may have a multilayer structure of alternating layers of GaN/InGaN-based materials, AlGaN/GaN-based materials or AlGaN/GaN/InGaN-based materials. The p-type nitride semiconductor layer may include a p-type superlattice layer, a p-type GaN layer on the p-type superlattice layer, and a p-type GaN contact layer on the p-type GaN layer.

A transparent electrode and a bonding electrode may be further provided on the p-type nitride semiconductor layer. The transparent electrode may be an oxide conductive layer having the property of light transmission.

The V-shaped distortion structure may be formed in succession in at least one of the n-type semiconductor layer, the active layer and the p-type semiconductor layer. The V-shaped distortion structure may be formed around a threading dislocation, increasing resistance in this area. Thus, current leakage caused by a threading dislocation is prevented and the effect of preventing electrostatic discharge (ESD) can be improved. Besides, the V-shaped distortion structure may serve to achieve luminance enhancement by forming an uneven structure at a semiconductor surface.

That is, the lattice mismatch between the sapphire substrate and the GaN semi-conductor formed on the sapphire substrate causes a threading dislocation. When static electricity is applied thereto, the threading dislocation concentrates the current and thus results in current leakage. For this reason, various studies have been conducted to reduce the threading dislocation causing current leakage and to therefore reduce the damage caused by ESD. According to the present invention, the V-shaped distortion structure is arbitrarily formed around the threading dislocation to increase resistance in the area of the threading dislocation. Accordingly, the current concentration in this area is prevented and ESD resistance can be enhanced. A layer with the V-shaped distortion structure may be formed at a low growth temperature of 600° C. to 900° C. or through chemical etching and regrowth. The blue LED chip completed in the aforesaid manner may be controlled to have the thickness ranging from 50 μm to 400 μm by controlling the thickness of a substrate through polishing, etching or the like.

The red fluorescent material for the output of white light may include a nitride-based fluorescent material containing N (e.g., CaAlSiN₃:Eu). The nitride-based red fluorescent material ensures higher reliability in external environments involving heat, moisture or the like, and less chance of discoloration than a sulfide-based fluorescent material. Particularly, high excitation efficiency of the fluorescent material is realized in the dominant wavelength of the blue LED chip defined within the specific range of 430 nm to 465 nm to obtain high color reproducibility. Other nitride-based fluorescent materials such as Ca₂Si₅N₈:Eu or sulfide-based fluorescent materials may be used as the red fluorescent material. As for the green fluorescent material, a nitride-based fluorescent materials such as β-SiAlON:Eu or a silicate-based fluorescent material such as (Baₓ,Sr_{y},Mg_{z})SiO₄:Eu²⁺, F, Cl (0<x, y≦2, 0≦z≦2, 0 ppm≦F, Cl≦5000000 ppm) may be used. The nitride-based and silicate-based fluorescent materials have high excitation efficiency within the dominant wavelength range of 430 nm to 465 nm.

Preferably, the full width at half maximum (FWHM) of the blue LED chip ranges from 10 nm to 50 nm, the FWHM of the green fluorescent material ranges from 30 nm to 150 nm, and the FWHM of the red fluorescent material ranges from about 50 nm to 200 nm. As each light source has the FWHM ranges as above, white light with higher color uniformity and color quality is obtained. Particularly, by limiting the dominant wavelength and the FWHM of the blue LED chip to 430 nm to 465 nm and 10 nm to 50 nm respectively, the efficiency of the CaAlSiN₃:Eu-based red fluorescent material and the efficiency of the β-SiAlON:Eu-based or (Baₓ,Sr_{y},Mg_{z})SiO₄:Eu²⁺, F, Cl (0<x, y≦2, 0≦z≦2, 0 ppm≦F, Cl≦5000000 ppm)-based green fluorescent material can be significantly enhanced. The blue LED chip may be replaced with an UV LED chip having a dominant wavelength in the range of 380 nm to 430 nm. In this case, to output white light, the light-transmissive, transparent resin 116 may include, at the least, blue, green and red fluorescent materials. The blue fluorescent material may be selected from the group consisting of (Ba, Sr, Ca)₅(PO₄)₃Cl:(Eu²⁺, Mn²+) and Y₂O₃:(Bi³⁺, Eu²⁺), and the green and red fluorescent materials may be selected from the group consisting of the YAG-based, TAG-based, silicate-based, sulfide-based and nitride-based fluorescent materials.

A white LED for emitting white light may be obtained without using a fluorescent material. For example, a second quantum well layer emitting light with a different wavelength (e.g., yellow light) from that of blue light may be further provided on and/or under a first quantum well layer of a nitride-based InGaN and/or GaN emitting blue light to obtain an LED chip emitting white light through combination with blue light. The quantum well layer may have a multiquantum well structure, and the first and second quantum well layers may be formed by controlling the amount of In in the InGaN forming the first and second well layers. If the first quantum well layer emits UV light of the wavelength ranging from 380 nm to 430 nm, the amount of In in the active layer may be controlled such that the second quantum well layer emits blue light and a third quantum well layer emits yellow light.

The recess 118 is the recessed top surface of the lead frame 112 and 113 exposed in the bottom of the cavity 117 to a predetermined depth.

The recess 118 is provided as a downwardly curved portion in one end portion of the lead frame 112, in which at least one LED chip 111 is mounted. The curved portion includes a mounting surface on which the LED chip 111 is mounted, and a pair of lower inclined surfaces 112a and 112a extending upwardly from both sides of the mounting surface, inclined at a predetermined angle and facing outer surfaces of the LED chip 111 respectively.

A reflective member may be provided at the lower inclined surfaces 112a and 112a to reflect light generated when the LED chip 111 emits light.

The adequate depth H of the recess 118 or the groove 118a ranges from 50 μm to 400 μm in due consideration of the height h of the LED chip 111 mounted therein. Thus, the height H of the cavity of the package body can be lowered to between 150 μm and 500 μm and the amount of light-transmissive, transparent resin filling the cavity decreases, thereby saving on manufacturing costs, enhancing luminance and contributing to the miniaturization of a product.

Respective end portions of the lead frames 112 and 113 facing outer surfaces of the LED chip 111 mounted in the groove 118a may include lower inclined surfaces 112b and 113b on which reflective members are respectively provided to reflect the light generated when the LED chip 111 emits light.

In the LED packages 100 and 100a having the above configurations, the top surface of the LED chip 111 located at the very center of the cavity 117 may be roughly flush with the top surfaces of the lead frames 112 and 113 because the LED chip 111 is mounted on the mounting surface of the downwardly curved portion of the lead frame 112 or in the groove 118a between facing end portions of the lead frames 112 and 113. Here, the top surface of the LED chip 11 is wire-bonded with the lead frames 112 and 113 through metal wires 114a and 114b, respectively.

In this case, the maximum heights of the metal wires 114a and 114b used for the wire bonding with the LED chip 111 can be reduced by the lowered mounting height of the LED chip 111.

Accordingly, the amount of transmissive transparent resin 116 filling the cavity 117 to protect the LED chip 111 and the metal wires 114a and 114b can be reduced, while the height H to which the transparent resin is filled can be lowered by the lowered mounting height of the LED chip 111. Consequently, the luminance of light from the LED chip can be relatively increased as compared to the related art.

As the height H of the transparent resin 116 in the cavity 117 is lowered, the height of the package body 115 is reduced by the lowered height H of the transparent resin 116. Accordingly, the entire package size can be minimized.

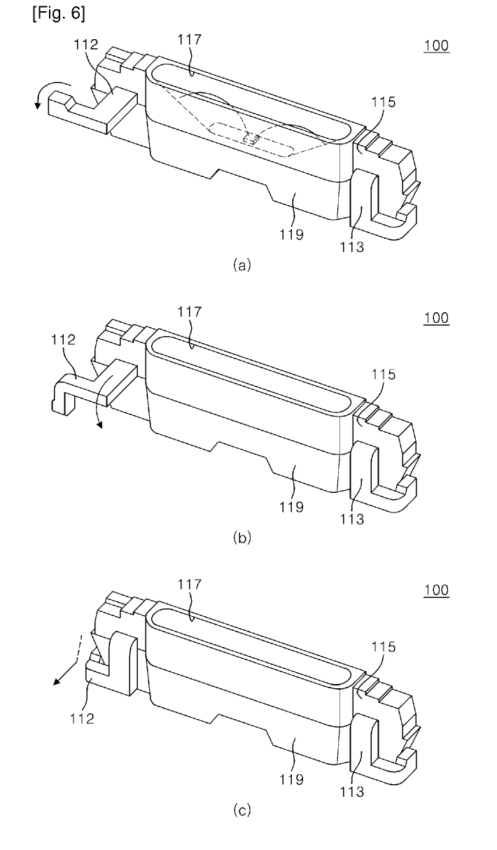

Referring to (a) through (c) of FIG. 6, cathode and anode lead frames 112 and 113 each are integrally fixed to the package body 115 and have an end portion exposed to an outer surface of the package body 115 to be connected with external power (see (a) of FIG. 6).

The lead frames 112 and 113 exposed on the downwards part of the package body 115 are each bent along a side surface and/or a lower surface of the package, thus being bent in an opposite direction to the light emitting side where the cavity 117 is formed.

In the package 100 of the present invention, the lead frames 112 and 113, downwardly exposed to the outside of the package, are each bent to a side portion and/or a back portion (rear or lower portion) of a mounting surface 119 (i.e., the bottom) of the package.

In the forming process, an end portion of the lead frame 112 exposed to the bottom of the package is bent first to correspond to the shape of the side surface of the package 100 (see (b) of FIG. 6), and then bent backwardly of the bottom 119 of the package, thereby completing the entire shape of the lead frame 122 (see (c) of FIG. 6).

While the present invention has been shown and described in connection with the exemplary embodiments, it will be apparent to those skilled in the art that modifications and variations can be made without departing from the spirit and scope of the invention as defined by the appended claims.

1. A light emitting diode (LED) package comprising:
a pair of lead frames connected with at least one LED chip through a metal wire;
a package body integrally fixed with the lead frames and having a cavity with an open top;
a lead frame bent downwardly to a lower part of an external mounting surface of the package body;
a light-transmissive, transparent resin covering the LED chip and filling the cavity;
a recess formed in a bottom surface of the cavity, in which the LED chip is mounted; and
a transparent resin including a fluorescent material formed in the recess and the cavity.

2. The LED package of claim 1, wherein the recess has a depth ranging from 50 μm to 400 μm.

3. The LED package of claim 1, wherein the fluorescent material is at least one of YAG-based, TAG-based, silicate-based, sulfide-based and nitride-based materials.

4. The LED package of claim 1, wherein the recess is provided between respective facing ends of the lead frames in the form of a groove having a predetermined depth.

5. The LED package of claim 4, wherein an end portion of the lead frame facing an outer surface of the LED chip has a lower inclined surface on which a reflective member reflecting light from the LED chip is provided.

6. The LED package of claim 1, wherein the cavity has an upper inclined surface on which a reflective member reflecting light from the LED chip is provided.
